(19) United States
(12) Patent Application Publication
(10) Pub. No.: US 2005/0236658 A1
(43) Pub. Date: Oct. 27, 2005

(54) Semiconductor device and production method therefor

(76) Inventor: Suguru Tahara, Shizuoka (JP)

Correspondence Address: RABIN & Berdo, PC, 1101 14TH STREET, NW, SUITE 500, WASHINGTON, DC, 20005, US

(21) Appl. No.: 11/089,021

(22) Filed: Mar. 25, 2005

(30) Foreign Application Priority Data
Mar. 26, 2004 (JP) 2004-093497

(51) Int. Cl. H01L 27/108

(52) U.S. Cl. 257/306

(57) ABSTRACT

A semiconductor device includes a lower electrode provided over a semiconductor substrate, a capacitor film provided on a surface of the lower electrode and having substantially the same pattern as the lower electrode, and an upper electrode provided on the capacitor film. The upper electrode is disposed in a predetermined region on the capacitor film with a margin of the capacitor film left uncovered with the upper electrode. The semiconductor device further includes a minute interconnection provided at the same level as the lower electrode and having a width of not greater than 0.5 μm.

### BACKGROUND OF THE INVENTION

1. Field of the Invention

The present invention relates to a semiconductor device having a capacitor element of an MIM (metal-insulator-metal) structure including a capacitor film held between an upper electrode and a lower electrode.

2. Description of Related Art

In a semiconductor device such as an LSI (large-scale integrated circuit), a capacitor element of an MIM structure including a capacitor film held between an upper electrode and a lower electrode is provided in a multi-level interconnection structure provided in a surface of the device. The capacitor element typically has a construction as schematically shown in FIG. 4. The capacitor element has an element structure of a so-called planar type which includes a lower electrode 1, a capacitor film 2 provided on the lower electrode 1 and substantially free from undulations and an upper electrode 3 provided on the capacitor film 2. The capacitor film 2 has a smaller plan area than the lower electrode 1, and the upper electrode 3 has the same pattern as the capacitor film 2. When the capacitor film 2 is formed by patterning in fabrication of the capacitor element, over-etching occurs, so that a step 4 is formed in a surface of the lower electrode 1 at an edge of the capacitor film 2 as shown in FIG. 5 on an enlarged scale.

FIGS. 6(A) to 6(D) are sectional views illustrating a process sequence for fabricating the capacitor element. First, a lower electrode film 11 is formed from a material for the lower electrode 1 on a surface of an inter-level insulation film 10 of a multi-level interconnection structure formed on a semiconductor substrate. Then, a dielectric film 12 is formed from a dielectric material for the capacitor film 2 on the lower electrode film 11, and an upper electrode film 13 is formed from a material for the upper electrode 3 on the dielectric film 12. In turn, a resist film 14 having a pattern for the capacitor film 2 and the upper electrode 3 is formed on the upper electrode film 13. This state is shown in FIG. 6(A).

In this state, the upper electrode film 13 and the dielectric film 12 are etched by dry etching (reactive ion etching) using the resist film 14 as a mask. Thus, a laminate structure including the capacitor film 2 and the upper electrode 3 is formed on the lower electrode film 11. This state is shown in FIG. 6(B). If an unnecessary portion of the dielectric film 12 on the lower electrode film 11 is assuredly removed, over-etching of a surface of the lower electrode film 11 inevitably occurs as described above.

Subsequently, a resist film 15 having a pattern for the lower electrode 1 is formed as covering a predetermined region of the resulting substrate including the laminate structure of the capacitor film 2 and the upper electrode 3 as shown in FIG. 6(C). Then, an unnecessary portion of the lower electrode film 11 on the inter-level insulation film 10 is removed by dry etching (reactive ion etching) using the resist film 15 as a mask, whereby the lower electrode 1 is formed as having a predetermined pattern as shown in FIG. 6(D).

Thereafter, the resist film 15 is removed. Thus, the capacitor element having the structure shown in FIG. 4 is provided.

When the lower electrode film 11 is subjected to the over-etching during the dry etching of the capacitor film 2 as shown in FIG. 6(B), the lower electrode film material is sputtered to be re-deposited on a side wall 2a of the capacitor film 2 (see FIG. 5). Since the side wall 2a is generally parallel to the direction of ion beams applied during the dry etching, a sputtering effect on the electrode material 9 deposited on the side wall 2a is small. As a result, the lower electrode film material remains on the side wall 2a of the capacitor film 2. Therefore, an electric current path is formed on the side wall 2a of the capacitor film 2. This causes a leak current 7, making it impossible to provide an intended charge accumulating effect. This may result in malfunction of the element.

An effective approach to suppression of the leak current 7 is to increase a distance between the lower electrode 1 and the upper electrode 3. If the thickness of the capacitor film 2 is increased to increase the distance between the upper electrode 3 and the lower electrode 1, however, the capacitance of the capacitor element is reduced. To overcome this drawback to satisfy a capacitance requirement, the plan areas of the lower electrode 1 and the upper electrode 3 should be increased. This prevents higher density integration of the semiconductor device (LSI) to increase the chip size of the LSI.

Where the capacitor film is formed as having an increased plan area, the formation of the capacitor film is conceivably achieved by first forming the lower electrode by patterning, and forming the capacitor film to cover upper and side surfaces of the lower electrode (see U.S. Pat. No. 6,144,053 and Japanese Unexamined Patent Publication No. 2002-98991). However, a relatively great step is formed on lateral sides of the lower electrode after the formation of the lower electrode. This makes it difficult to perform micro-processing in the photoresist step.

Where a minute interconnection (plug or the like) 8 and the lower electrode 1 are simultaneously formed at the same level as shown in FIGS. 6(c) and 6(D), the minute interconnection 8 fails to have an intended shape.

More specifically, a resist pattern 15a having a line width corresponding to the line width (e.g., 0.5 μm or less) of the minute interconnection 8 is formed as shown in FIG. 6(C) for the formation of the minute interconnection 8. The resist pattern 15a is a part of the resist film 15, which is used as a mask for dry etching of the lower electrode film 11 to form the lower electrode 1 and the minute interconnection 8.

However, the resist pattern 15a having a minute line width is more rapidly eroded than a lower electrode resist pattern of the resist film 15 having a greater plan area. Therefore, the resist pattern 15a is completely removed by the dry etching before the unnecessary portion of the lower electrode film 11 around the lower electrode 1 is completely removed. Since the dry etching is still continued, an upper portion 8a of the minute interconnection 8 is etched to be tapered.

As a result, the minute interconnection 8 does not have a designed sectional shape, failing to have intended electrical characteristics. Where the minute interconnection 8 is an inter-level interconnection plug, a failure in inter-level interconnection will occur, making the semiconductor device per se defective.

### SUMMARY OF THE INVENTION

It is an object of the present invention to provide a semiconductor device including a capacitor element having a construction which suppresses or prevents a leak current between an upper electrode and a lower electrode.

It is another object of the present invention to provide a semiconductor device having a construction which ensures that a minute interconnection can properly be formed at the same level as a lower electrode.

It is further another object of the present invention to provide a production method for a semiconductor device including a planar-type capacitor element having a construction which effectively suppresses or prevents a leak current between an upper electrode and a lower electrode.

It is still another object of the present invention to provide a semiconductor device production method which can properly form a minute interconnection at the same level as a lower electrode.

According to the present invention, there is provided a semiconductor device, which includes a lower electrode provided over a semiconductor substrate, a capacitor film provided on a surface of the lower electrode and having the same pattern as the lower electrode, an upper electrode provided in a predetermined region on the capacitor film with a margin of the capacitor film left uncovered with the upper electrode, and a minute interconnection provided at the same level as the lower electrode and having a width of not greater than 0.5 μm. The semiconductor substrate is herein defined as a bare semiconductor substrate, a semiconductor substrate having an insulation film formed on a surface thereof, or a semiconductor substrate having an inter-level interconnection structure formed on a surface thereof. This definition is also applied to the following description.

With the aforesaid arrangement, the lower electrode and the capacitor film have the same pattern, and the upper electrode is provided on the capacitor film with the margin of the capacitor film left uncovered. Therefore, a distance between the lower electrode and the upper electrode is represented by a sum of the width of the margin of the capacitor film uncovered with the upper electrode and the thickness of the capacitor film (at an edge of the capacitor film). Thus, the distance between the upper electrode and the lower electrode is increased without increasing the thickness of the capacitor film, so that a leak current between the upper and lower electrodes can be suppressed.

The lower electrode is covered with the capacitor film. Therefore, when the minute interconnection having a width of not greater than 0.5 μm is formed at the same level as the lower electrode, a dielectric film is left on the minute interconnection at the same level as the capacitor film, and used as a mask for processing the minute interconnection. Thus, the minute interconnection can be formed as having an intended sectional shape and a width of not greater than 0.5 μm at the same level as the lower electrode.

According to the present invention, there is provided a semiconductor device production method, which includes the steps of: forming a lower electrode film of an electrode material over a semiconductor substrate; forming a dielectric film of a dielectric material for a capacitor film on the lower electrode film; forming an upper electrode film of an electrode material on the dielectric film; forming a first resist film having a pattern for an upper electrode on the upper electrode film; performing a first etching process for etching the upper electrode film by using the first resist film as a mask to form the upper electrode, and stopping the etching with the dielectric film around the upper electrode left substantially unetched after the dielectric film is exposed; forming a second resist film [including a lower electrode resist pattern portion] which covers a region of the resulting substrate including the upper electrode and a portion of the dielectric film around the upper electrode; and performing a second etching process for etching the dielectric film and the lower electrode film by using the second resist film as a mask to form a capacitor film and a lower electrode having the same pattern.

According to the present invention, when the upper electrode film is etched by using the first resist film as the mask to form the upper electrode in a predetermined pattern, the etching is stopped with the dielectric film around the upper electrode left substantially unetched. Therefore, after the dielectric film and the lower electrode film are etched by using the second resist film as the mask, the capacitor film obtained by patterning the dielectric film has a margin uncovered with the upper electrode around the upper electrode. A distance between the upper electrode and the lower electrode is represented by a sum of the width of the margin of the capacitor film and the thickness of the capacitor film. Therefore, a leak current between the upper and the lower electrodes can be suppressed. In addition, a surface of the margin of the capacitor film is covered with the second resist film when the lower electrode film is etched. This suppresses re-deposition of the lower electrode film material on the margin surface, whereby the leak current can more effectively be suppressed.

Thus, the suppression of the leak current can be achieved without increasing the thickness of the capacitor film. The patterning of the lower electrode film does not precede the patterning of the dielectric film, but the capacitor film and the lower electrode are formed as having the same pattern by using the second resist film as the mask after the patterning of the upper electrode film. Thus, a capacitor element of a so-called planar type with its capacitor film being substantially free from undulations is fabricated. Therefore, the fabrication of the capacitor element can be achieved through a photolithography process without formation of a great step on the semiconductor substrate. This allows for proper micro-processing.

The second resist film forming step may include the step of forming a resist film having a minute interconnection resist pattern portion for a minute interconnection having a width of not greater than 0.5 μm in addition to a lower electrode resist pattern portion for the lower electrode. In this case, the second etching step preferably includes the step of etching the lower electrode film by using the second resist film and a portion of the dielectric film covered with the minute interconnection resist pattern portion as a mask to simultaneously form the lower electrode and the minute interconnection having a width of not greater than 0.5 μm at the same level.

According to this method, the second resist film has the minute interconnection resist pattern portion for the minute interconnection having a width of not greater than 0.5 μm. Therefore, when the lower electrode film is etched, the minute interconnection resist pattern portion of the second resist film and the dielectric film portion covered with the minute interconnection resist pattern portion serve as the mask for the formation of the minute interconnection. Thus, when the etching is continued after the minute interconnection resist pattern portion above the minute interconnection is completely removed by the etching, the erosion of the minute interconnection is suppressed by the dielectric film portion. Thus, the minute interconnection can properly be formed as having an intended sectional shape and a width of not greater than 0.5 μm at the same level as the lower electrode. As a result, the minute interconnection thus formed has characteristics as designed.

The foregoing and other objects, features and effects of the present invention will become more apparent from the following detailed description of the preferred embodiments with reference to the attached drawings.

### BRIEF DESCRIPTION OF THE DRAWINGS

FIG. 1 is a schematic sectional view for explaining the construction of a characteristic portion of a semiconductor device according to one embodiment of the present invention;

FIGS. 2(A) to 2(E) are schematic sectional views illustrating a process sequence for production of the semiconductor device shown in FIG. 1;

FIG. 3 is a sectional view for explaining a specific example of the semiconductor device according to the embodiment;

FIG. 4 is a schematic sectional view for explaining the construction of a prior-art planar-type capacitor element;

FIG. 5 is a schematic sectional view illustrating a part of the capacitor element of FIG. 4 on an enlarged scale; and

FIGS. 6(A) to 6(D) are schematic sectional views illustrating a process sequence for fabricating the capacitor element of FIG. 4.

### DETAILED DESCRIPTION OF PREFERRED EMBODIMENTS

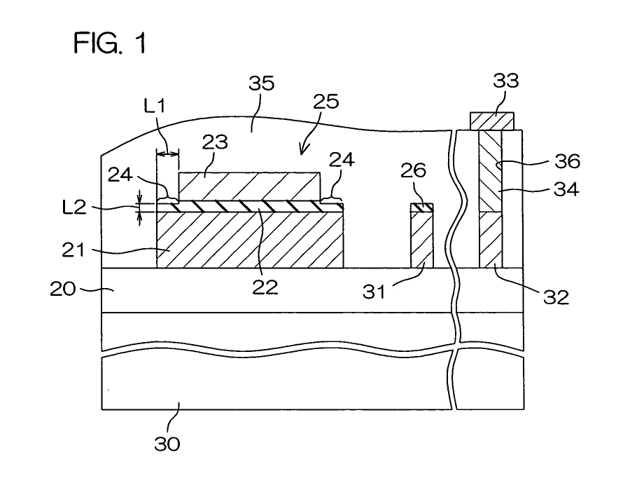

FIG. 1 is a schematic sectional view for explaining the construction of a characteristic portion of a semiconductor device according to one embodiment of the present invention. A multi-level interconnection structure is provided on a semiconductor substrate 30, and a capacitor element 25 is provided on an inter-level insulation film 20 of the multi-level interconnection structure. The capacitor element 25 has an MIM structure including a capacitor film 22 held between a lower electrode 21 and an upper electrode 23. That is, the lower electrode 21 is provided on a surface of the inter-level insulation film 20, and the capacitor film 22 is provided on a surface of the lower electrode 21. Further, the upper electrode 23 is provided on a surface of the capacitor film 22. The capacitor element 25 is of a so-called planar type with its capacitor film 22 being substantially free from undulations.

The capacitor film 22 is composed of a dielectric material such as silicon oxide, and has the same pattern as the lower electrode 21. The upper electrode 23 is disposed on the capacitor film 22 with a margin 24 of the capacitor film 22 left uncovered with the upper electrode 23 and, hence has a smaller plan area than the capacitor film 22. A surface of the margin 24 of the capacitor film 22 uncovered with the upper electrode 23 is located closer to the lower electrode 21 than an interface between the upper electrode 23 and the capacitor film 22 due to over-etching of the capacitor film occurring in patterning of the upper electrode 23.

Minute interconnections 31, 32 each having a width of not greater than 0.5 μm are provided on the inter-level insulation film 20 at the same level as the lower electrode 21. For example, the minute interconnection 31 serves for interconnection within the same level, while the minute interconnection 32 serves as a plug for connection to an interconnection 33 at an upper level. A dielectric film 26 composed of the same dielectric material as the capacitor film 22 is provided on a surface of the minute interconnection 31. A dielectric film similar to the dielectric film 26 (not shown in FIG. 1) is formed on the minute interconnection 32 at a certain stage of a production process, but etched away when a plug portion 34 is formed for the connection to the interconnection 33 at the upper level. A reference numeral 35 denotes an inter-level insulation film.

In the capacitor element 25 of the semiconductor device of this embodiment, a distance (leak current path length) between the upper electrode 23 and the lower electrode 21 is represented by a sum of the width L1 of the uncovered margin 24 of the capacitor film 22 and the thickness L2 of the capacitor film 22 at an edge of the capacitor film 22. Therefore, the distance between the upper electrode 23 and the lower electrode 21 is much greater than in the prior art in which the distance (leak current path length) between the upper electrode and the lower electrode is represented by the thickness of the capacitor film at an edge of the capacitor film. In addition, there is no need to increase the thickness of the capacitor film 22 to increase the distance between the upper electrode 23 and the lower electrode 21, obviating the need for increasing the plan area of the upper electrode 23 or the lower electrode 21 and hence allowing for higher density integration of the semiconductor device.

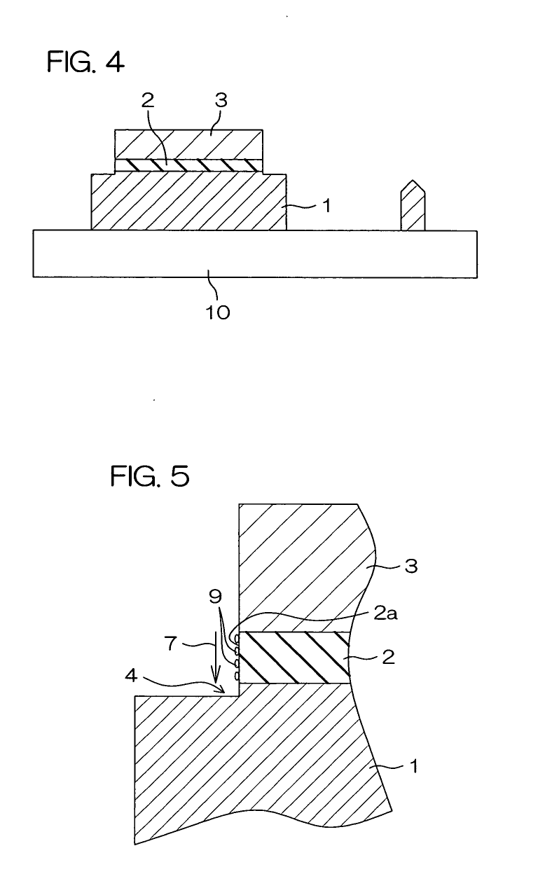

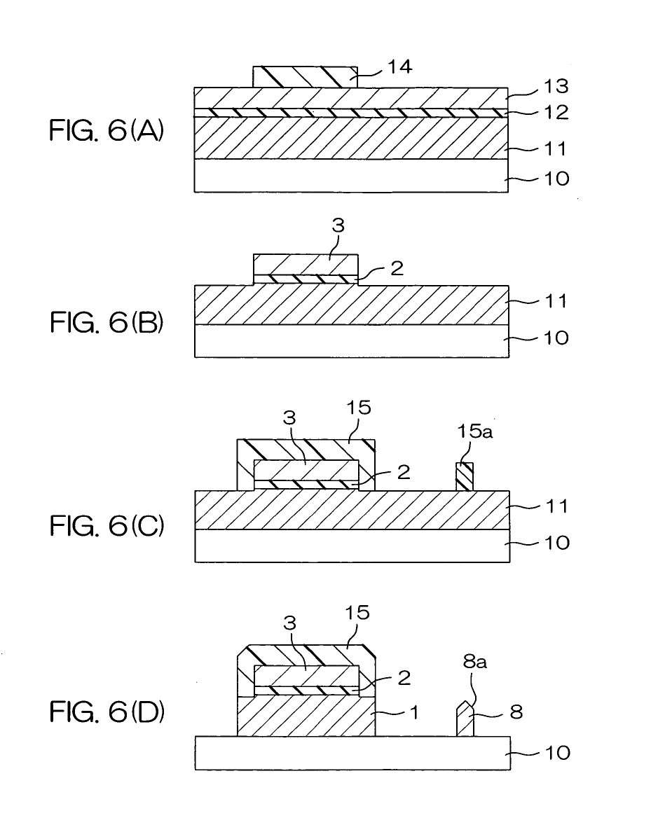

The inventor of the present invention experimentally confirmed that a leak current between the upper electrode 23 and the lower electrode 21 is on the order of 1.0×10⁻¹¹ A in the capacitor element 25 according to the embodiment shown in FIG. 1 while a leak current between the upper electrode 3 and the lower electrode 1 is on the order of 1.0×10⁻⁷ A in the capacitor element according to the prior art shown in FIG. 4.

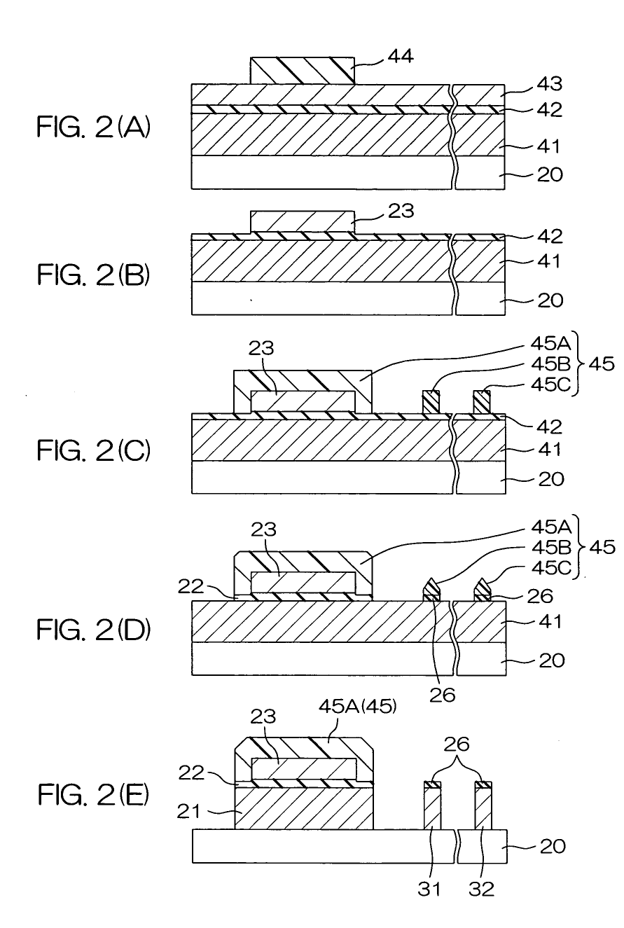

FIGS. 2(A) to 2(E) are schematic sectional views illustrating a process sequence for production of the semiconductor device shown in FIG. 1. As shown in FIG. 2(A), a lower electrode film 41 is first formed from a material for the lower electrode 21 on the inter-level insulation film 20. A dielectric film 42 is formed from a dielectric material for the capacitor film 22 on the lower electrode film 41, and an upper electrode film 43 is formed from a material for the upper electrode 23 on the dielectric film 42. Then, a resist film 44 (first resist film) having a pattern for the upper electrode 23 is formed on the upper electrode film 43.

The materials for the lower electrode film 41 and the upper electrode film 43 may be any electrically conductive electrode materials. In this embodiment, the lower electrode film 41 and the upper electrode film 43 are each composed of a laminate film including a lower layer of an aluminum alloy and an upper layer of a titanium compound (TiN). The laminate film can be formed by a sputtering method. For example, the lower electrode film 41 has a thickness of about 200 nm to about 500 nm, and the upper electrode film 43 has a thickness of about 100 nm to about 150 nm. Besides the laminate film, a single layer film of polycrystalline silicon having an electrical conductivity increased by introduction of an impurity is usable as the lower electrode film 41 and the upper electrode film 43.

The dielectric film 42 is composed of a silicon oxide film, for example, which is formed by CVD (chemical vapor deposition) at a temperature of 400° C. to 450° C. Besides the silicon oxide film, a silicon nitride film, an SiON film and a ferroelectric film are usable as the dielectric film 42. Where the oxide film is used, the dielectric film 42 has a thickness of 20 nm to 50 nm. Where the nitride film which has a higher dielectric constant than the oxide film is used, the thickness of the dielectric film 42 is increased to provide a capacitance equivalent to that provided when the oxide film is used. Where the SiON film is used, the SiON dielectric film 42 advantageously serves as a reflection prevention film in KrF laser lithography.

Where the lower electrode film 41 and the upper electrode film 43 are each composed of the laminate film having the aluminum alloy layer and the titanium compound (TiN) layer, the titanium compound (TiN) layer serves as a reflection prevention film in i-ray lithography. In this case, micro-processing can advantageously be performed.

As shown in FIG. 2(B), an unnecessary portion of the upper electrode film 43 is removed by dry etching (reactive ion etching) using the resist film 44 as a mask. Thus, the upper electrode 23 is formed. At this time, a surface of the dielectric film 42 is over-etched to completely remove the unnecessary portion of the upper electrode film 43. The dry-etching of the upper electrode film 43 is stopped with the dielectric film 42 left unetched on the lower electrode film 41 (see FIG. 2(B)).

As shown in FIG. 2(C), a resist film 45 (second resist film) including a lower electrode resist portion 45A for the lower electrode 21 and minute electrode resist portions 45B, 45C for the minute interconnections 31, 32 are formed on the resulting substrate. The lower electrode resist portion 45A covers a region of the resulting substrate having a greater plan area than the upper electrode 23 and including the upper electrode 23 and a portion of the dielectric film 42 (entirely) surrounding the upper electrode 23. The minute electrode resist portion 45B has a minute pattern for the minute interconnection 31 having a width of not greater than 0.5 μm. Similarly, the minute electrode resist portion 45C has a minute pattern for the minute interconnection 32 having a width of not greater than 0.5 μm.

Dry etching (reactive ion etching) is performed by using the resist film 45 as a mask. In fabrication of the planar type capacitor element 25, the dielectric film 42 is substantially free from undulations, because the formation of the upper electrode film 43 precedes the patterning of the lower electrode film 41. Therefore, the upper electrode film 43 can have a smaller thickness. Since the upper electrode 23 provided by the patterning has a smaller step at its edge, the resist film 45 can be formed at a higher level of accuracy for realizing a minute line width for the minute interconnections 31, 32. The resist film 45 may have a thickness (about 0.5 μm) suitable for the formation of the minute interconnections 31, 32.

FIG. 2(D) shows a state in which the capacitor film 22 and dielectric film portions 26 on the minute interconnections 31, 32 remain after the unnecessary portion of the dielectric film 42 is removed. By further performing the dry etching in this state, an unnecessary portion of the lower electrode film 41 is removed to form the lower electrode 21 and the minute interconnections 31, 32 at the same level as shown in FIG. 2(E).

During the dry etching, erosion of the resist film 45 occurs such that a resist pattern having a greater plan area is slowly eroded and a resist pattern having a smaller plan area is rapidly eroded. Therefore, the minute electrode resist portions 45B, 45C of the resist film 45 are completely etched away during the etching of the lower electrode film 41. However, the dielectric film portions 26 on the minute interconnections 31, 32 thereafter function as an etching mask, thereby preventing the minute interconnections 31, 32 under the dielectric film portions 26 from being eroded before the unnecessary portion of the lower electrode film 41 is completely removed. Thus, the minute interconnections 31, 32 are formed as having predetermined sectional shapes at the same level as the lower electrode 21.

Reference is made again to FIG. 1 for the explanation.

Thereafter, the resist film 45 is removed, and the resulting substrate including the capacitor element 25 and the minute interconnections 31, 32 is covered with an inter-level insulation film 35. Then, a via-hole 36 is formed above the minute interconnection 32 in the inter-level insulation film 35, and a metal material is filled in the via-hole 36 to form the upper plug portion 34 of the interconnection plug. Subsequently, the interconnection 33 for the upper level is formed on the inter-level insulation film 35. Thus, the semiconductor device shown in FIG. 1 is provided.

According to this embodiment, the distance between the upper electrode 23 and the lower electrode 21 is increased without increasing the thickness of the capacitor film 22, so that the leak current can be suppressed. In addition, the minute interconnections 31, 32 can be formed as having an intended sectional shape and hence having designed electrical characteristics at the same level as the lower electrode 21. Since the capacitor film 22 is covered with the resist film 45 in the etching of the lower electrode film 41, it is possible to suppress re-deposition of the lower electrode film material on a surface of the capacitor film 22. This more effectively reduces the leak current between the upper electrode 23 and the lower electrode 21.

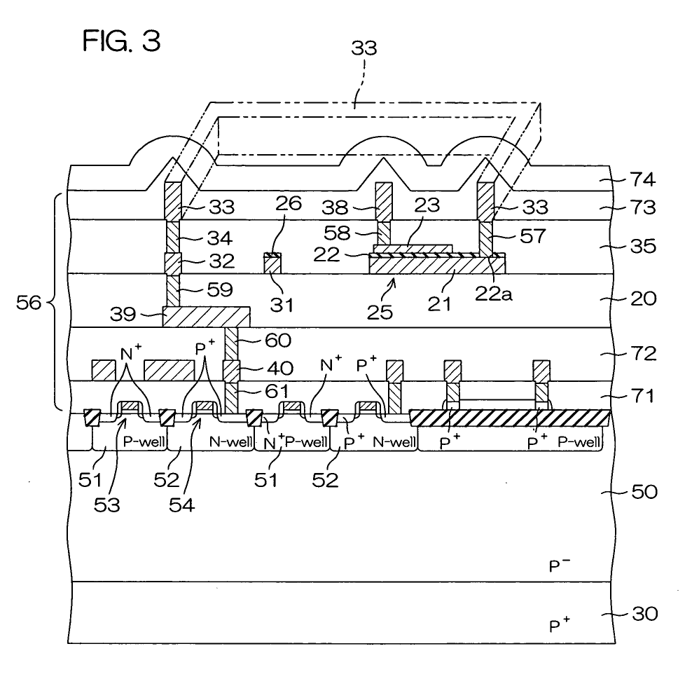

FIG. 3 is a sectional view for explaining a specific example of the semiconductor device according to this embodiment. A P⁻-type epitaxial layer 50 is provided on a surface of a P type semiconductor substrate 30. P-type wells 51 and N-type wells 52 are provided in the P⁻-type epitaxial layer 50. N-channel MOS FETs (field effect transistors) 53 are respectively provided in the P-type wells 51, and P-channel MOS FETs 54 are respectively provided in the N-type wells 52. That is, these transistors 53, 54 are connected in a predetermined manner to form CMOS structures in the epitaxial layer 50. Thus, the semiconductor device is a CMOS-type LSI.

A multi-level interconnection structure 56 including multiple interconnection levels isolated from each other by inter-level insulation films 20, 35, 71, 72, 73 of SiO₂. A reference numeral 74 denotes a surface protection film composed of a plasma SiN film.

The structure shown in FIG. 1 is incorporated in the multi-level interconnection structure 56. The lower electrode 21 of the capacitor element 25 is connected to an inter-level interconnection plug 57 via a contact hole 22a formed in the capacitor film 22, and the inter-level interconnection plug 57 is connected to the interconnection 33. The upper electrode 23 is connected to an interconnection 38 provided at the same level as the interconnection 33 via an interconnection plug 58.

On the other hand, the interconnection 33 is routed within this level and connected to the inter-level interconnection plug 34 on the minute interconnection 32. The minute interconnection 32 is further connected to an interconnection 39 at a lower level via an inter-level interconnection plug 59. Then, the interconnection 39 is connected to the P-channel MOS FET 54 via an interconnection plug 60, a minute interconnection 40 and an interconnection plug 61.

Further, the minute interconnection 32 is provided at the same level as the lower electrode 21 and the minute interconnection 31.

The minute interconnections 31, 32 and the lower electrode 21 are composed of a metal film having a laminate structure, for example, including TiN/Ti/AlCu/Ti/TiN/Ti The interconnections 33, 38 are composed of an interconnection film having a laminate structure including TiN/AlCu/Ti/TiN/Ti.

While one embodiment of the present invention has thus been described, the invention may be embodied in other ways. Although the embodiment described above is directed to a case where the 0.5-μm wide minute interconnections 31, 32 are formed at the same level as the lower electrode 21, the process shown in FIGS. 2(A) to 2(E) is applicable to a case where a minute interconnection having a width of not greater than 0.25 μm is formed at the same level as the lower electrode 21.

While the present invention has been described in detail with reference to the embodiment thereof, it should be understood that the foregoing disclosure is merely illustrative of the technical principles of the present invention but not limitative of the same. The spirit and scope of the present invention are to be limited only by the appended claims.

This application corresponds to Japanese Patent Application No. 2004-93497 filed with the Japanese Patent Office on Mar. 26, 2004, the disclosure of which is incorporated herein by reference.

1. A semiconductor device comprising:
a lower electrode provided over a semiconductor substrate;
a capacitor film provided on a surface of the lower electrode and having substantially the same pattern as the lower electrode;
an upper electrode provided in a predetermined region on the capacitor film with a margin of the capacitor film left uncovered with the upper electrode; and
a minute interconnection provided at the same level as the lower electrode and having a width of not greater than 0.5 μm.

2. A semiconductor device production method comprising the steps of:
forming a lower electrode film of an electrode material over a semiconductor substrate;
forming a dielectric film of a dielectric material for a capacitor film on the lower electrode film;
forming an upper electrode film of an electrode material on the dielectric film;
forming a first resist film having a pattern for an upper electrode on the upper electrode film;
performing a first etching process for etching the upper electrode film by using the first resist film as a mask to form the upper electrode, and stopping the etching with the dielectric film around the upper electrode left substantially unetched after the dielectric film is exposed;
forming a second resist film which covers a region of the resulting substrate including the upper electrode and a portion of the dielectric film around the upper electrode; and
performing a second etching process for etching the dielectric film and the lower electrode film by using the second resist film as a mask to form the capacitor film and a lower electrode having the same pattern.

3. A semiconductor device production method as set forth in claim 2, wherein
the second resist film forming step includes the step of forming a resist film having a minute interconnection resist pattern portion for a minute interconnection having a width of not greater than 0.5 μm in addition to a lower electrode resist pattern portion for the lower electrode, and
the second etching step includes the step of etching the lower electrode film by using the second resist film and a portion of the dielectric film covered with the minute interconnection resist pattern portion as a mask to simultaneously form the lower electrode and the minute interconnection having a width of not greater than 0.5 μm at the same level.
